(19) United States
(12) Patent Application Publication
(10) Pub. No.: US 2025/0210538 A1
(43) Pub. Date: Jun. 26, 2025

(54) APPARATUS, SYSTEM, AND METHOD FOR UNIQUELY IDENTIFYING INDIVIDUAL DIES ACROSS DIE STACKS

(71) Applicant: Advanced Micro Devices, Inc., Santa Clara, CA (US)

(72) Inventors: Richard Martin Born, Ft. Collins, CO (US); John Wuu, Ft. Collins, CO (US)

(73) Assignee: Advanced Micro Devices, Inc., Santa Clara, CA (US)

(21) Appl. No.: 18/395,203

(22) Filed: Dec. 22, 2023

(51) Int. Cl. H01L 23/544; H01L 21/68

(52) U.S. Cl. CPC H01L 23/544; H01L 21/68; H01L 2223/54413; H01L 2223/54433

(57) ABSTRACT

An exemplary apparatus for uniquely identifying individual dies across die stacks includes a die stack and a plurality of signals arranged across the die stack. The plurality of signals are manipulated to form a unique identifier for each die included in the die stack. Various other apparatuses, systems, and methods are also disclosed.

### BACKGROUND

Die stacks include multiple dies that are stacked together. In some examples, a die stack is coupled to a base die that manages the die stack. In one example, the base die needs to distinguish the individual dies included in the die stack for addressing purposes. The instant disclosure, therefore, identifies and addresses a need for apparatuses, systems, and methods that facilitate and/or support uniquely identifying individual dies across die stacks.

### BRIEF DESCRIPTION OF THE DRAWINGS

The accompanying drawings illustrate a number of exemplary implementations and are a part of the specification. Together with the following description, these drawings demonstrate and explain various principles of the instant disclosure.

FIG. 1 is an illustration of an exemplary apparatus for uniquely identifying individual dies across die stacks according to one or more implementations of this disclosure.

FIG. 2 is an illustration of an exemplary apparatus for uniquely identifying individual dies across die stacks according to one or more implementations of this disclosure.

FIG. 3 is an illustration of an exemplary apparatus for uniquely identifying individual dies across die stacks according to one or more implementations of this disclosure.

FIG. 4 is an illustration of an exemplary implementation of signals being swizzled relative to a sequence arranged across a die stack according to one or more implementations of this disclosure.

FIG. 5 is an illustration of an exemplary system for uniquely identifying individual dies across die stacks according to one or more implementations of this disclosure.

FIG. 6 is an illustration of an exemplary system for uniquely identifying individual dies across die stacks according to one or more implementations of this disclosure.

FIG. 7 is a flowchart of an exemplary method for uniquely identifying individual dies across die stacks according to one or more implementations of this disclosure.

Throughout the drawings, identical reference characters and descriptions indicate similar, but not necessarily identical, elements. While the exemplary implementations described herein are susceptible to various modifications and alternative forms, specific implementations have been shown by way of example in the drawings and will be described in detail herein. However, the exemplary implementations described herein are not intended to be limited to the particular forms disclosed. Rather, the instant disclosure covers all modifications, equivalents, and alternatives falling within the scope of the appended claims.

### DETAILED DESCRIPTION OF EXEMPLARY IMPLEMENTATIONS

The present disclosure describes various apparatuses, systems, and methods for uniquely identifying individual dies across die stacks. In some examples, a die stack can include and/or represent multiple dies that are stacked together. In one example, the dies included in the die stack need to be distinguished from one another for addressing purposes. As a specific example, a die stack can be coupled to a base die whose circuitry controls, directs, and/or manages the die stack in one way or another. In this example, multiple signals are arranged, configured, and/or disposed across the die stack. These signals can be manipulated in one way or another (e.g., via digital logic and/or swizzling) to form and/or create a unique identifier for each die included in the die stack. The base die and/or the die stack can utilize the unique identifiers to distinguish the individual dies included in the die stack from one another and/or to facilitate and/or support addressing the individual dies.

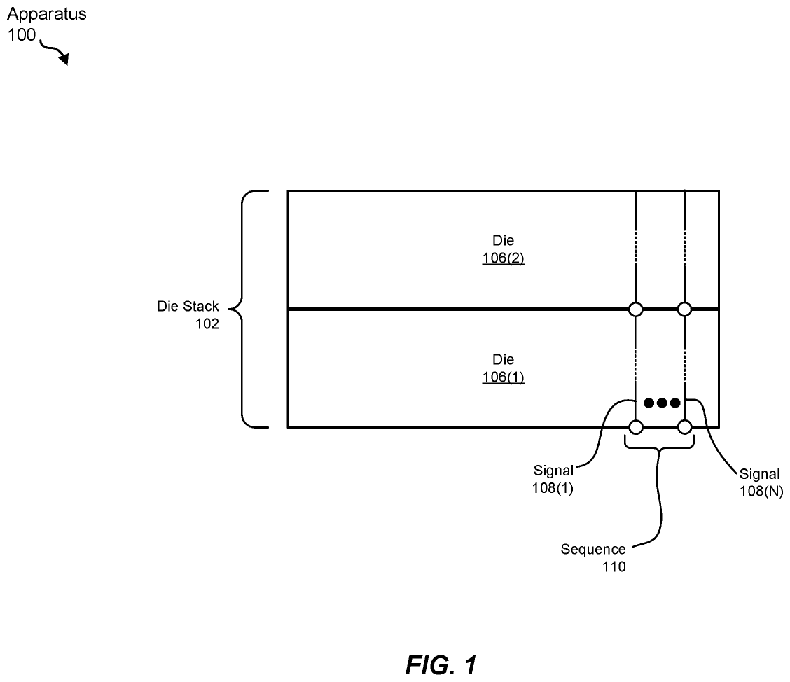

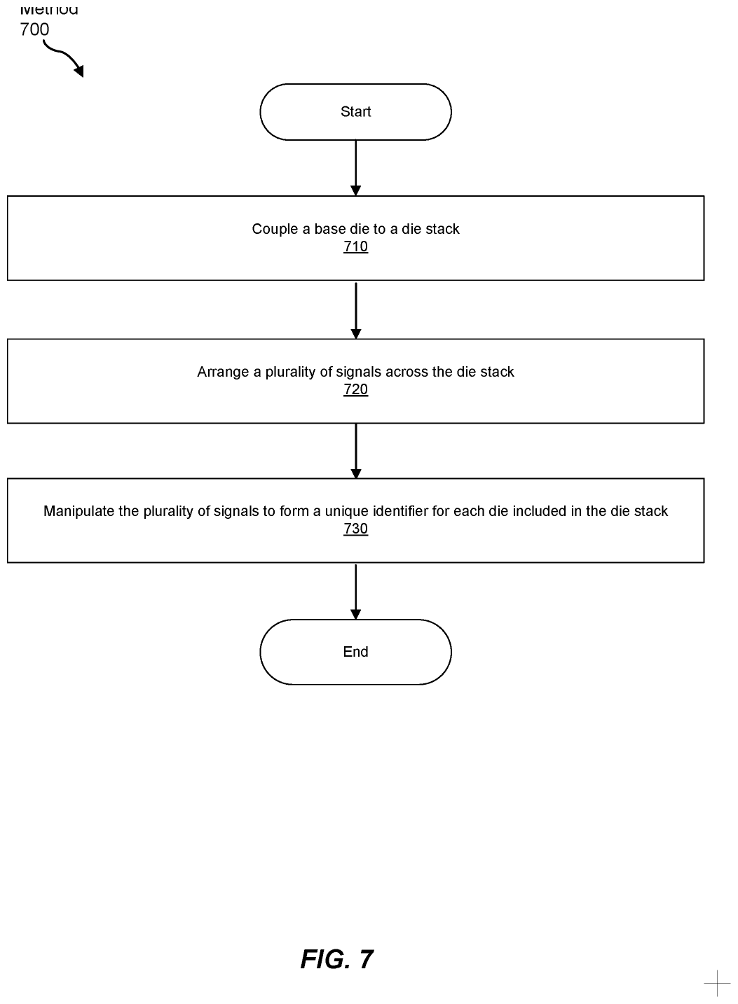

The following will provide, with reference to FIGS. 1-6, detailed descriptions of exemplary apparatuses, systems, and/or corresponding implementations for uniquely identifying individual dies across die stacks. Detailed descriptions of an exemplary method for uniquely identifying individual dies across die stacks will be provided in connection with FIG. 7.

FIG. 1 illustrates an exemplary apparatus 100 that facilitates and/or supports uniquely identifying individual dies across die stacks. As illustrated in FIG. 1, exemplary apparatus 100 can include and/or represent a die stack 102 and signals 108(1)-(N). In some examples, die stack 102 can include and/or represent at least dies 106(1) and 106(2). In one example, signals 108(1)-(N) can be arranged and/or configured in a sequence 110 across die stack 102.

In some examples, signals 108(1)-(N) can be manipulated, altered, and/or modified in one way or another between dies 106(1) and 106(2). For example, signals 108(1)-(N) can be swizzled between dies 106(1) and 106(2) by shifting, rotating, and/or changing the positions of signals 108(1)-(N) in sequence 110. In this example, through swizzling, signals 108(1)-(N) can render, deliver, and/or provide data that constitutes and/or represents different unique identifiers for dies 106(1) and 106(2). In one example, signals 108(1)-(N) can include and/or represent immutable and/or fixed binary or digital signals that are manipulated at least in part by swizzling to form and/or create the unique identifiers across die stack 102.

In some examples, data conveyed and/or passed by signals 108(1)-(N) can be increased, decreased, and/or otherwise modified by digital logic between dies 106(1) and 106(2). For example, a digital adder circuit can increment (e.g., add one to) the data represented by signals 108(1)-(N) between certain points on dies 106(1) and 106(2). In another example, a digital subtractor circuit can decrement (e.g., subtract one from) the data represented by signals 108(1)-(N) between certain points on dies 106(1) and 106(2). In a further example, a linear-feedback shift register can modify (e.g., pseudo-randomize) the data represented by signals 108(1)-(N) between certain points on dies 106(1) and 106(2). By modifying the data in these ways, the digital logic can enable signals 108(1)-(N) to render, deliver, and/or provide different unique identifiers for dies 106(1) and 106(2).

As a specific example, signals 108(1)-(N) can render, deliver, and/or provide a unique identifier of “00” to circuitry incorporated on die 106(1). In this example, after being manipulated, signals 108(1)-(N) can render, deliver, and/or provide a unique identifier of “01” to circuitry incorporated on die 106(2).

In some examples, sequence 110 can constitute and/or represent a certain physical layout of signals 108(1)-(N) across die stack 102. For example, sequence 110 in FIG. 1 can include and/or represent two physical positions on each of dies 106(1) and 106(2). In one example, these positions can remain aligned and/or the same across each die included in die stack 102. In other words, the specific location and/or placement of sequence 110 can be consistent across dies 106(1) and 106(2).

In some examples, sequence 110 can constitute and/or represent physical positions and/or locations of signals 108(1)-(N) within a certain area of each of dies 106(1) and 106(2) and/or along the back or side of each of dies 106(1) and 106(2). In one example, signal 108(1) can be shifted and/or moved in one direction (e.g., to the right) relative to sequence 110 between certain points on dies 106(1) and 106(2). In this example, signal 108(N) can be shifted and/or moved in the opposite direction (e.g., to the left) relative to sequence 110 between certain points on dies 106(1) and 106(2).

In some examples, dies 106(1) and 106(2) can each include and/or represent a small, diced piece of semiconductor material. In one example, dies 106(1) and 106(2) can each include and/or contain one or more circuits that consist of various electrical and/or electronic components (such as resistors, capacitors, transistors, memory units, processing devices, etc.). In this example, such circuits can be integrated into and/or created on dies 106(1) and 106(2) by a variety of fabrication processes. Examples of such fabrication processes include, without limitation, lamination, lithography, etching, deposition, chemical mechanical planarization, oxidation, ion implantation, photolithography, diffusion, combinations or variations of one or more of the same, and/or any other suitable fabrication processes.

In some examples, die stack 102 can include and/or represent a compilation and/or assortment of dies that are stacked on top of one another and/or physically or electrically coupled to one another. In one example, all or a portion of dies 106(1) and 106(2) can include and/or represent duplicates and/or copies of one another. For example, dies 106(1) and 106(2) can constitute and/or represent topologically or electrically identical copies of one another. Additionally or alternatively, dies 106(1) and 106(2) can be coupled, attached, and/or interfaced with one another via bonds, landing pads (e.g., hybrid-bond landing pads), through-silicon vias (TSVs), microbumps, and/or die-to-die interconnects.

In some examples, die stack 102 can be incorporated and/or packaged in or as an integrated circuit. For example, die stack 102 can constitute and/or represent a set of dies that include one or more memory and/or cache circuits. Additionally or alternatively, die stack 102 can constitute and/or represent a set of dies that include one or more processor and/or ASIC circuits. In one example, the integrated circuit can include and/or represent one or more semiconductor devices and/or components implemented or deployed as part of a computing system. Examples of such an integrated circuit include, without limitation, processing devices, microprocessors, microcontrollers, central processing units (CPUs), field-programmable gate arrays (FPGAs), application-specific integrated circuits (ASICs), systems on chips (SoCs), parallel accelerated processors, tensor cores, chiplets, memory devices, caches, portions of one or more of the same, variations or combinations of one or more of the same, and/or any other suitable integrated circuits.

In some examples, die stack 102 can be coupled, attached, and/or mounted to a substrate. In one example, all the dies included in die stack 102 can be stacked together using TSVs and then attached to the substrate as a stack. In a further example, a silicon interposer can be attached to the substrate first, after which die stack 102 and/or other components can be attached to the silicon interposer (in, e.g., a “2.5D” and/or “3D” package).

In some examples, signals 108(1)-(N) can each include and/or represent electrically conductive traces, paths, and/or connections that carry analog and/or digital data across die stack 102. In one example, signals 108(1)-(N) can be separated and/or electrically insulated from one another as necessary to form one or more circuits that incorporate electrical components and/or electronics across die stack 102. Signals 108(1)-(N) can each include and/or represent any type or form of electrically conductive material. Examples of such electrically conductive material include, without limitation, copper, aluminum, silver, gold, alloys of one or more of the same, combinations or variations of one or more of the same, and/or any other suitable materials.

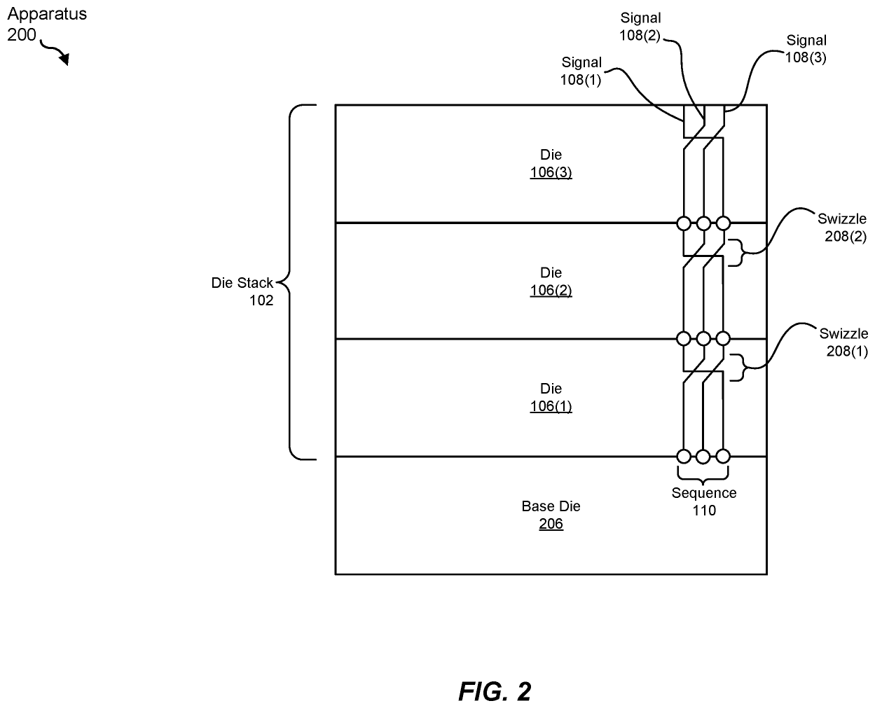

FIG. 2 illustrates an exemplary apparatus 200 for uniquely identifying individual dies across die stacks. In some examples, apparatus 200 can include and/or represent certain components and/or features that perform and/or provide functionalities that are similar and/or identical to those described above in connection with FIG. 1. As illustrated in FIG. 2, apparatus 200 can include and/or represent die stack 102, signals 108(1)-(3), and a base die 206. In one example, die stack 102 can include and/or represent dies 106(1)-(3). In this example, signals 108(1)-(3) can be arranged and/or configured in sequence 110 across die stack 102.

In some examples, signals 108(1)-(3) can be swizzled relative to sequence 110 across die stack 102. For example, signals 108(1)-(3) can be swizzled by shifting, rotating, and/or changing positions in sequence 110 between die 106(1), die 106(2), and/or die 106(3). In one example, the number of dies included in die stack 102 can correspond to and/or match the number of signals involved in the swizzling relative to sequence 110 across die stack 102. For example, die stack 102 in FIG. 2 can include and/or represent three dies, and signals 108(1)-(3) can include and/or represent three signals.

In some examples, sequence 110 in FIG. 2 can include and/or represent a first position, a second position, and a third position that are aligned across die stack 102. In one example, signal 108(1) can be coupled and/or fixed to the first position on die 106(1). In this example, signal 108(2) can be coupled and/or fixed to the second position on die 106(1). Additionally or alternatively, signal 108(3) can be coupled and/or fixed to the third (and final) position on die 106(1).

In some examples, a swizzle 208(1) can involve shifting and/or moving signal 108(1) to the second position on die 106(2), signal 108(2) to the third (and final) position on die 106(2), and/or signal 108(3) to the first position on die 106(2). Additionally or alternatively, a swizzle 208(2) can involve shifting and/or moving signal 208(1) to the third (and final) position on die 106(3), signal 108(2) to the first position on die 106(3), and/or signal 108(3) to the second position on die 106(3).

In some examples, signals 108(1)-(3) can be arranged and/or patterned in the same way on both base die 206 and die 106(1). Additionally or alternatively, signals 108(1)-(3) can be arranged and/or patterned in the first, second, and third positions of sequence 110 on both base die 206 and die 106(1) and/or across the interface between base die 206 and die 106(1). In one example, sequence 110 can span and/or extend from base die 206 across die stack 102.

As a specific example, signals 108(1)-(3) can render, deliver, and/or provide a unique identifier of “001” to circuitry incorporated on die 106(1). In this example, signals 108(1)-(3) can render, deliver, and/or provide a unique identifier of “010” to circuitry incorporated on die 106(2). Additionally or alternatively, signals 108(1)-(3) can render, deliver, and/or provide a unique identifier of “100” to circuitry incorporated on die 106(3).

In some examples, base die 206 can include and/or represent a small, diced piece of semiconductor material. In one example, base die 206 can each include and/or contain one or more circuits that consist of various electrical and/or electronic components (such as resistors, capacitors, transistors, memory units, processing devices, etc.). For example, base die 206 can include and/or represent a compute die and/or core complex die (CCD) whose circuitry controls, directs, and/or manages die stack 102 in one way or another. In this example, such circuitry can be integrated into and/or created on base die 206 by a variety of fabrication processes. Examples of such fabrication processes include, without limitation, lamination, lithography, etching, deposition, chemical mechanical planarization, oxidation, ion implantation, photolithography, diffusion, combinations or variations of one or more of the same, and/or any other suitable fabrication processes.

In some examples, base die 206 can be physically and/or electrically coupled to die stack 102. For example, base die 206 can be directly attached to die 106(1) included in die stack 102. In one example, base die 206 can be topologically and/or electrically distinct from some or all of the dies included in die stack 102. Additionally or alternatively, base die 206 can be coupled, attached, and/or interfaced with die 106(1) via bonds, landing pads (e.g., hybrid-bond landing pads), TSVs, microbumps, and/or die-to-die interconnects.

In one example, all or a portion of dies 106(1)-(3) can include and/or represent duplicates and/or copies of one another. For example, dies 106(1)-(3) can constitute and/or represent topologically or electrically identical copies of one another. Additionally or alternatively, dies 106(1)-(3) can be coupled, attached, and/or interfaced with one another via bonds, landing pads (e.g., hybrid-bond landing pads), TSVs, microbumps, and/or die-to-die interconnects.

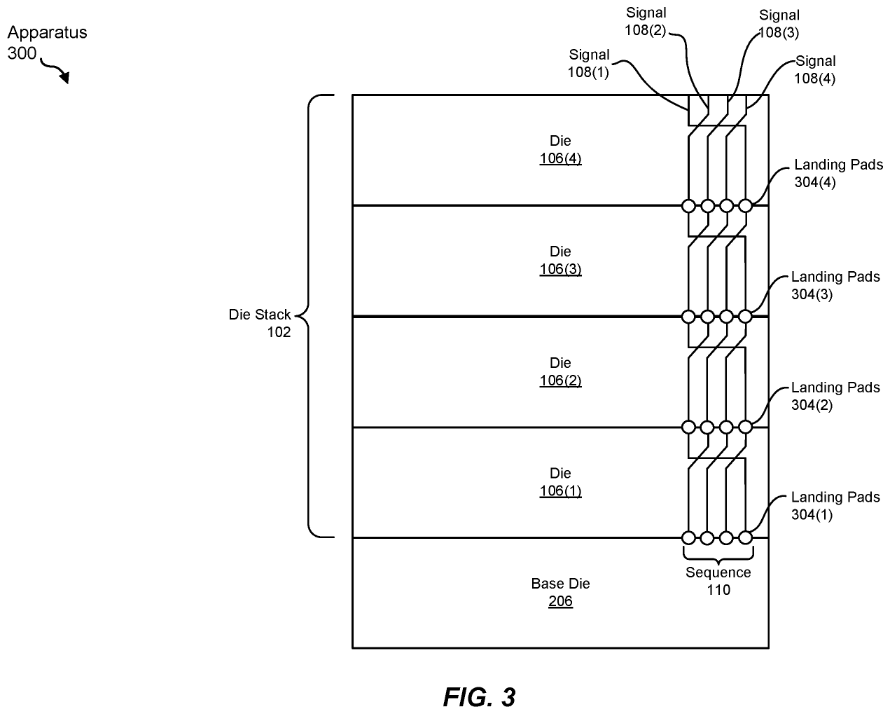

FIG. 3 illustrates an exemplary apparatus 300 for uniquely identifying individual dies across die stacks. In some examples, apparatus 300 can include and/or represent certain components and/or features that perform and/or provide functionalities that are similar and/or identical to those described above in connection with either of FIGS. 1 and 2. As illustrated in FIG. 3, apparatus 300 can include and/or represent die stack 102, signals 108(1)-(4), and base die 206. In one example, die stack 102 can include and/or represent dies 106(1)-(4). In this example, signals 108(1)-(4) can be arranged and/or configured in sequence 110 across die stack 102.

In some examples, signals 108(1)-(4) can be swizzled relative to sequence 110 across die stack 102. For example, signals 108(1)-(4) can shift, rotate, and/or change positions in sequence 110 between die 106(1), die 106(2), die 106(3), and/or die 106(4). In one example, the number of dies included in die stack 102 can correspond to and/or match the number of signals involved in the swizzling relative to sequence 110 across die stack 102. For example, die stack 102 in FIG. 3 can include and/or represent four dies, and signals 108(1)-(4) can include and/or represent four signals.

In some examples, sequence 110 in FIG. 3 can include and/or represent a first position, a second position, a third position, and a fourth position that are aligned across die stack 102. In one example, signal 108(1) can be coupled and/or fixed to the first position on die 106(1). In this example, signal 108(2) can be coupled and/or fixed to the second position on die 106(1). Additionally or alternatively, signal 108(3) can be coupled and/or fixed to the third position on die 106(1). Finally, signal 108(4) can be coupled and/or fixed to the fourth (and final) position on die 106(1).

In some examples, signal 108(1) can be shifted and/or moved to the second position on die 106(2). In one example, signal 108(2) can be shifted and/or moved to the third position on die 106(2). Additionally or alternatively, signal 108(3) can be shifted and/or moved to the fourth (and final) position on die 106(2). Finally, signal 108(4) can be shifted and/or moved to the first position on die 106(2).

In some examples, signal 108(1) can be shifted and/or moved to the third position on die 106(3). In one example, signal 108(2) can be shifted and/or moved to the fourth (and final) position on die 106(3). Additionally or alternatively, signal 108(3) can be shifted and/or moved to the first position on die 106(3). Finally, signal 108(4) can be shifted and/or moved to the second position on die 106(3).

In some examples, signal 108(1) can be shifted and/or moved to the fourth (and final) position on die 106(4). In one example, signal 108(2) can be shifted and/or moved to the first position on die 106(4). Additionally or alternatively, signal 108(3) can be shifted and/or moved to the second position on die 106(4). Finally, signal 108(4) can be shifted and/or moved to the third position on die 106(4).

As a specific example, signals 108(1)-(4) can render, deliver, and/or provide a unique identifier of “0001” to circuitry incorporated on die 106(1). In this example, signals 108(1)-(4) can render, deliver, and/or provide a unique identifier of “0010” to circuitry incorporated on die 106(2). Additionally or alternatively, signals 108(1)-(4) can render, deliver, and/or provide a unique identifier of “0100” to circuitry incorporated on die 106(3). Finally, signals 108(1)-(4) can render, deliver, and/or provide a unique identifier of “1000” to circuitry incorporated on die 106(4).

In one example, all or a portion of dies 106(1)-(4) can include and/or represent duplicates and/or copies of one another. For example, dies 106(1)-(4) can constitute and/or represent topologically or electrically identical copies of one another. Additionally or alternatively, dies 106(1)-(4) can be coupled, attached, and/or interfaced with one another via bonds, landing pads (e.g., hybrid-bond landing pads), TSVs, microbumps, and/or die-to-die interconnects. For example, apparatus 300 can also include and/or represent landing pads 304(1), 304(2), 304(3), and 304(4) that couple, bond, and/or attach signals 108(1)-(4) to certain positions in sequence 110 on each die included in die stack 102 and/or across the interfaces between one or more of base die 206 and/or dies 106(1)-(4). In this example, landing pads 304(1)-(4) can positioned, located, and/or placed to shoot and/or protrude out the back of dies 106(1)-(4), respectively.

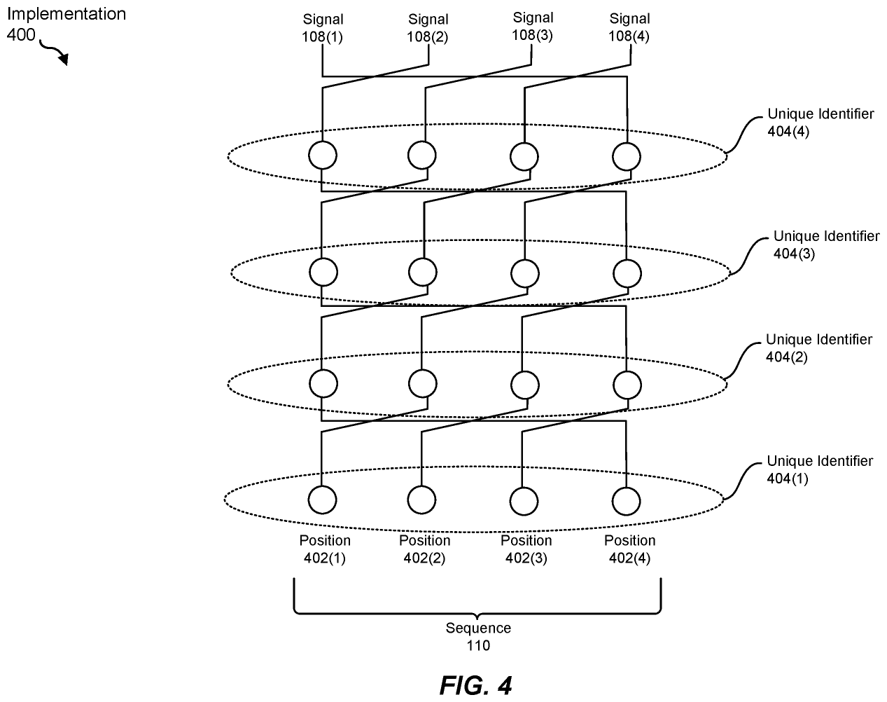

FIG. 4 illustrates an exemplary implementation 400 for uniquely identifying individual dies across die stacks. In some examples, implementation 400 can include and/or represent certain components and/or features that perform and/or provide functionalities that are similar and/or identical to those described above in connection with any of FIGS. 1-3. As illustrated in FIG. 4, implementation 400 can include and/or represent a certain pattern of signals 108(1)-(4) that are swizzled relative to sequence 110 across die stack 102. For example, sequence 110 can include and/or represent positions 402(1), 402(2), 402(3), and/or 402(4). In this example, signals 108(1)-(4) can be coupled and/or fixed to positions 402(1)-(4), respectively, on die 106(1), and signals 108(1)-(4) can be coupled and/or fixed to positions 402(2), 402(3), 402(4), and 402(1), respectively, on die 106(2). Additionally or alternatively, signals 108(1)-(4) can be coupled and/or fixed to positions 402(3), 402(4), 402(1), and 402(2), respectively, on die 106(3), and signals 108(1)-(4) can be coupled and/or fixed to positions 402(4), 402(1), 402(2), and 402(3), respectively, on die 106(4).

In some examples, the swizzling (e.g., shifting, rotating, and/or changing positions in sequence 110) can be performed and/or accomplished on the dies included in die stack 102. For example, after the landing pads on die 106(1), signals 108(1)-(4) can be swizzled relative to positions 402(1)-(4) on die 106(1) before reaching die 106(2) and/or the landing pads on die 106(2). In this example, after the landing pads on die 106(2), signals 108(1)-(4) can be further swizzled relative to positions 402(1)-(4) on die 106(2) before reaching die 106(3) and/or the landing pads on die 106(3). Additionally or alternatively, after the landing pads on die 106(3), signals 108(1)-(4) can be further swizzled relative to positions 402(1)-(4) on die 106(3) before reaching die 106(4) and/or the landing pads on die 106(4).

In some examples, the pattern of signals 108(1)-(4) on die 106(1) can form, constitute, and/or represent a unique identifier 404(1) used by circuitry on base die 206 and/or die 106(1). In such examples, the pattern of signals 108(1)-(4) on die 106(2) can form, constitute, and/or represent a unique identifier 404(2) used by circuitry on base die 206 and/or die 106(2). In one example, the pattern of signals 108(1)-(4) on die 106(3) can form, constitute, and/or represent a unique identifier 404(3) used by circuitry on base die 206 and/or die 106(3). Additionally or alternatively, the pattern of signals 108(1)-(4) on die 106(4) can form, constitute, and/or represent a unique identifier 404(4) used by circuitry on base die 206 and/or die 106(4).

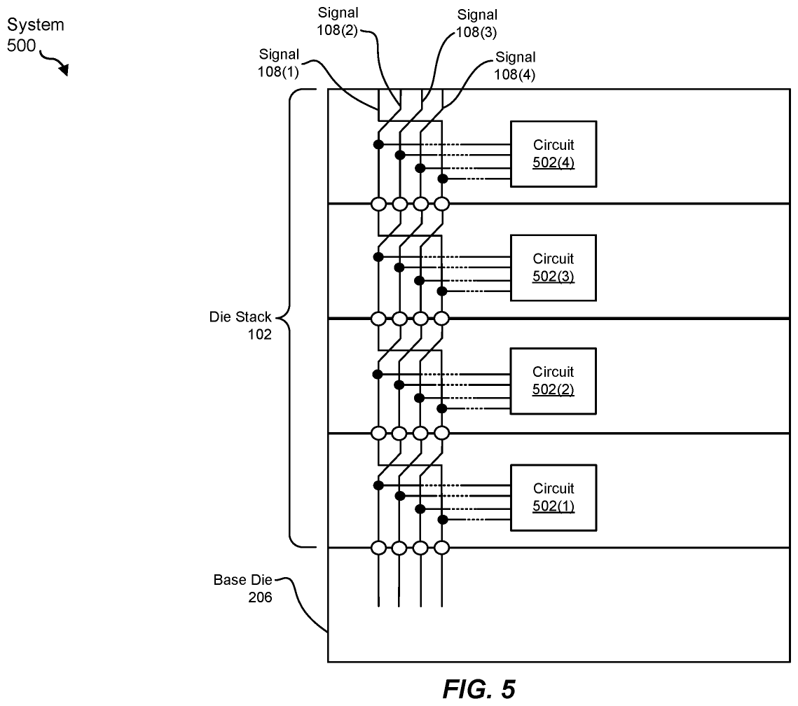

FIG. 5 illustrates an exemplary system 500 for uniquely identifying individual dies across die stacks. In some examples, system 500 can include and/or represent certain components and/or features that perform and/or provide functionalities that are similar and/or identical to those described above in connection with any of FIGS. 1-4. As illustrated in FIG. 5, system 500 can include and/or represent an implementation of apparatus 300 in which different unique identifiers are distributed across die stack 102 that includes dies 104(1)-(4). In one example, dies 106(1)-(4) can include and/or represent circuits 502(1)-(4), respectively.

In some examples, circuits 502(1)-(4) can be configured and/or programmed to perform one or more operations, measurements, and/or actions based at least in part on unique identifiers 404(1)-(4), respectively. In one example, circuits 502(1)-(4) can generate and/or compute a response and/or output based at least in part on unique identifiers 404(1)-(4), respectively. Additionally or alternatively, system 500 can include and/or represent a swizzled grouping of signals 108(1)-(4) that ascends and/or descends across die stack 102 and/or base die 206.

In some examples, base die 206 can be configured and/or programmed to perform one or more operations, measurements, and/or actions in connection with die stack 102 based at least in part on unique identifiers 404(1)-(4), respectively. In one example, base die 206 can generate and/or compute a response and/or output in connection with die stack 102 based at least in part on unique identifiers 404(1)-(4), respectively.

In some examples, circuit 502(1) can be configured to tap into and/or connect to signals 108(1)-(4) to obtain, draw, and/or read unique identifier 404(1). In one example, circuit 502(2) can be configured to tap into and/or connect to signals 108(1)-(4) to obtain, draw, and/or read unique identifier 404(2). In this example, circuit 502(3) can be configured to tap into and/or connect to signals 108(1)-(4) to obtain, draw, and/or read unique identifier 404(3). Additionally or alternatively, circuit 502(4) can be configured to tap into and/or connect to signals 108(1)-(4) to obtain, draw, and/or read unique identifier 404(4).

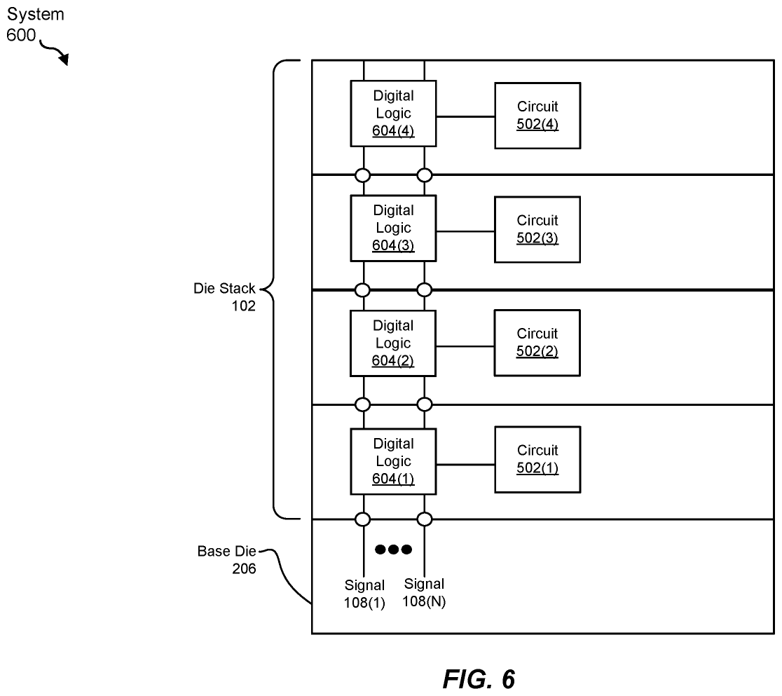

FIG. 6 illustrates an exemplary system 600 for uniquely identifying individual dies across die stacks. In some examples, system 600 can include and/or represent certain components and/or features that perform and/or provide functionalities that are similar and/or identical to those described above in connection with any of FIGS. 1-5. As illustrated in FIG. 6, system 600 can include and/or represent die stack 102 and base die 206. In one example, dies 106(1)-(4) can include and/or represent digital logics 604(1)-(4) that manipulate, alter, and/or change signals 108(1)-(N) to form and/or create a unique identifier for each of dies 106(1)-(4). In this example, the unique identifiers for dies 106(1)-(4) can differ and/or vary from one another.

In some examples, digital logics 604(1)-(4) can be communicatively and/or electrically coupled to circuits 502(1)-(4), respectively. In one example, digital logics 604(1)-(4) can each include and/or represent one or more combinations of logic gates that manipulate, alter, and/or change signals 108(1)-(N). Additionally or alternatively, digital logics 604(1)-(4) can include and/or represent certain electrical components (e.g., diodes, transistors, switches, etc.) that perform Boolean functions and/or logical operations based on given inputs. Examples of logic gates capable of forming digital logics 604(1)-(4) include, without limitation, AND gates, OR gates, NAND gates, NOR gates, XOR gates, XNOR gates, inverters, combinations or variations of one or more of the same, and/or any other suitable logic gates.

In some examples, the unique identifiers produced by signals 108(1)-(N) can collectively amount to a number that is at least twice as high (or twice as much) as the total number of signals 108(1)-(N). For example, two signals can be manipulated by digital logics 604(1)-(4) to produce four unique identifiers across die stack 102. Additionally or alternatively, three signals can be manipulated by digital logics 604(1)-(4) to produce eight unique identifiers across die stack 102. Accordingly, the number of unique identifiers produced by signals 108(1)-(N) can be equal to and/or commensurate with 2\hat{ }^{Total Number of Signals}.

As a specific example, digital logics 604(1)-(4) can each include and/or represent an adder circuit that increments (e.g., adds one to) the data transmitted, conveyed, and/or passed by two signals. For example, two signals can transmit, convey, and/or pass a unique identifier of “00” from base die 206 to die 106(1). In this example, the unique identifier for die 106(1) can be “00,” which is transmitted, conveyed, and/or passed from base die 206 to digital logic 604(1) and/or circuit 502(1). Accordingly, circuit 502(1) can receive “00” as its unique identifier from the signals and/or digital logic 604(1). In one example, the adder circuit included in digital logic 604(1) can increment and/or add one to the “00” unique identifier for die 106(1). In this example, the adder circuit included in digital logic 604(1) can output and/or produce “01” as the unique identifier for die 106(2).

Continuing with the specific example, two signals can transmit, convey, and/or pass the unique identifier of “01” from die 106(1) to die 106(2). In this example, the unique identifier for die 106(2) can be “01,” which is transmitted, conveyed, and/or passed from die 106(1) to digital logic 604(2) and/or circuit 502(2). Accordingly, circuit 502(2) can receive “01” as its unique identifier from the signals and/or digital logic 604(2). In one example, the adder circuit included in digital logic 604(2) can increment and/or add one to the “01” unique identifier for die 106(2). In this example, the adder circuit included in digital logic 604(2) can output and/or produce “10” as the unique identifier for die 106(3).

Continuing with the specific example, two signals can transmit, convey, and/or pass the unique identifier of “10” from die 106(2) to die 106(3). In this example, the unique identifier for die 106(3) can be “10,” which is transmitted, conveyed, and/or passed from die 106(2) to digital logic 604(3) and/or circuit 502(3). Accordingly, circuit 502(3) can receive “10” as its unique identifier from the signals and/or digital logic 604(3). In one example, the adder circuit included in digital logic 604(3) can increment and/or add one to the “10” unique identifier for die 106(3). In this example, the adder circuit included in digital logic 604(3) can output and/or produce “11” as the unique identifier for die 106(4).

Continuing with the specific example, two signals can transmit, convey, and/or pass the unique identifier of “11” from die 106(3) to die 106(4). In this example, the unique identifier for die 106(4) can be “11,” which is transmitted, conveyed, and/or passed from die 106(3) to digital logic 604(4) and/or circuit 502(4). Accordingly, circuit 502(4) can receive “11” as its unique identifier from the signals and/or digital logic 604(4). In one example, the adder circuit included in digital logic 604(4) can increment and/or add one to the “11” unique identifier for die 106(4). In this example, as die 106(4) is the top or end of die stack 102, the output of the adder circuit included in digital logic 604(4) can be discarded and/or go unused.

In one example, system 600 may include and/or represent a shift register (e.g., a linear-feedback shift register) that shifts a pattern of signals 108(1)-(N). For example, base die 206 and die stack 102 may form and/or establish a shift register with N bits in each die included in die stack 102. In this example, the shift register may shift a pattern of signals 108(1)-(N) starting at base die 206 and continuing through each die included in die stack 102. Assuming that die stack 102 includes X dies, the pattern of signals 108 may be shifted N*X times to produce and/or render a unique identifier for and/or in each die included in die stack 102. This shift-register configuration may rely on and/or utilize a single wire along with a separate clock signal to facilitate, provide, and/or support the creation of unique identifiers for each die included in die stack.

In some examples, die stack 102 may include and/or represent a shared configuration bus. In one example, each die included in die stack 102 may assume and/or be configured to operate as though it is the top of die stack 102. In this example, each die included in die stack 102 may isolate its outputs that are fed to the next and/or adjacent die.

In some examples, base die 206 may issue and/or transmit an identifier command to die 106(1) included in die stack 102 over the shared configuration bus. In one example, because die 106(1) included in die stack 102 is directly connected to base die 206, circuit logic 604(1) of die 106(1) may receive, obtain, and/or detect the identifier command via the shared configuration bus. In this example, the identifier command may include and/or represent a unique identifier along with an indicator of whether or not die 106(1) constitutes and/or represents the top of die stack 102. Additionally or alternatively, circuit logic 604(1) of die 106(1) may accept, adopt, and/or capture the unique identifier from the identifier command. Upon doing so, circuit logic 604(1) of die 106(1) may ignore and/or disregard subsequent identifier commands. Circuit logic 604(1) of die 106(1) may also determine and/or learn that die 106(1) is not the top of die stack 102 from the indicator included in and/or represented by the identifier command.

In some examples, base die 206 may issue and/or transmit another identifier command to die 106(2) included in die stack 102 over the shared configuration bus. In one example, because die 106(1) included in die stack 102 has already been assigned a unique identifier, circuit logic 604(2) of die 106(2) may receive, obtain, and/or detect the other identifier command via the shared configuration bus. In this example, the other identifier command may include and/or represent another unique identifier along with another indicator of whether or not die 106(2) constitutes and/or represents the top of die stack 102. Additionally or alternatively, circuit logic 604(2) of die 106(2) may accept, adopt, and/or capture the other unique identifier from the other identifier command. Upon doing so, circuit logic 604(2) of die 106(2) may ignore and/or disregard subsequent identifier commands. Circuit logic 604(2) of die 106(2) may also determine and/or learn that die 106(2) is not the top of die stack 102 from the other indicator included in and/or represented by the other identifier command.

By iteratively configuring each die included in die stack 102 in this way, system 600 and/or base die 206 may ensure that all the dies included in die stack 102 are assigned unique identifiers. In some examples, the unique identifiers may be used to address and/or handle other configuration commands on the shared configuration bus. In one example, the shared configuration bus may include and/or represent a serial bus equipped with a certain number of signals and/or pins that facilitate, provide, and/or support configuration data. Accordingly, the shared configuration bus may be able to carry, transfer, and/or transmit certain configuration and/or status data in addition to the unique identifiers.

In some examples, die stack 102 may implement a swizzling feature and/or technique to carry, transfer, and/or transmit analog signals to the individual dies. By doing so, die stack 102 may avoid, mitigate, and/or eliminate the need for analog multiplexers to properly share those analog signals among the individual dies. In other examples, die stack 102 may implement an adding, shifting, and/or sequencing feature or technique to carry, transfer, and/or transmit digital signals to the individual dies.

In some examples, the various devices and/or systems described in connection with FIGS. 1-6 can include and/or represent one or more additional circuits, components, and/or features that are not necessarily illustrated and/or labeled in FIGS. 1-6. For example, the apparatuses, implementations, and systems in FIG. 1-6 can also include and/or represent additional computing devices, analog and/or digital circuitry, onboard logic, transmitters, receivers, transceivers, transistors, resistors, capacitors, diodes, multiplexers, inductors, switches, registers, flipflops, connections, traces, buses, semiconductor (e.g., silicon) devices and/or structures, processing devices, storage devices, circuit boards, packages, substrates, housings, combinations or variations of one or more of the same, and/or any other suitable components that facilitate and/or support uniquely identifying individual dies across die stacks. In certain implementations, one or more of these additional circuits, components, devices, and/or features can be inserted and/or applied between any of the existing circuits, components, and/or devices illustrated in FIGS. 1-6 consistent with the aims and/or objectives provided herein. Accordingly, the electrical and/or communicative couplings described with reference to FIGS. 1-6 can be direct connections with no intermediate components, devices, and/or nodes or indirect connections with one or more intermediate components, devices, and/or nodes.

In some examples, the phrase “to couple” and/or the term “coupling,” as used herein, can refer to a direct connection and/or an indirect connection. For example, a direct coupling between two components can constitute and/or represent a coupling in which those two components are directly connected to each other by a single node that provides electrical continuity from one of those two components to the other. In other words, the direct coupling can exclude and/or omit any additional components between those two components.

Additionally or alternatively, an indirect coupling between two components can constitute and/or represent a coupling in which those two components are indirectly connected to each other by multiple nodes that fail to provide electrical continuity from one of those two components to the other. In other words, the indirect coupling can include and/or incorporate at least one additional component between those two components.

FIG. 7 is a flow diagram of an exemplary method 700 for uniquely identifying individual dies across die stacks. In one example, the steps shown in FIG. 7 can be performed and/or executed during the manufacture, creation, and/or assembly of a base die and/or die stack. Additionally or alternatively, the steps shown in FIG. 7 can also incorporate and/or involve various sub-steps and/or variations consistent with the descriptions provided above in connection with FIGS. 1-6.

As illustrated in FIG. 7, exemplary method 700 includes and/or involves the step of coupling a base die to a die stack (710). Step 710 can be performed in a variety of ways, including any of those described above in connection with FIGS. 1-6. For example, a computing equipment manufacturer and/or subcontractor can couple, attach, and/or interface a base die to a die stack.

Exemplary method 700 also includes and/or involves the step of arranging a plurality of signals across the die stack (720). Step 720 can be performed in a variety of ways, including any of those described above in connection with FIGS. 1-6. For example, a computing equipment manufacturer and/or subcontractor can arrange, dispose, and/or configure a plurality of signals across the die stack.

Exemplary method 700 further includes the step of manipulating the plurality of signals to form a unique identifier for each die included in the die stack (730). Step 730 can be performed in a variety of ways, including any of those described above in connection with FIGS. 1-6. For example, a computing equipment manufacturer and/or subcontractor can manipulate, alter, and/or modify the plurality of signals to form a unique identifier for each die included in the die stack.

While the foregoing disclosure sets forth various implementations using specific block diagrams, flowcharts, and examples, each block diagram component, flowchart step, operation, and/or component described and/or illustrated herein can be implemented, individually and/or collectively, using a wide range of hardware, software, or firmware (or any combination thereof) configurations. In addition, any disclosure of components contained within other components should be considered exemplary in nature since many other architectures can be implemented to achieve the same functionality. Furthermore, the various steps, events, and/or features performed by such components should be considered exemplary in nature since many alternatives and/or variations can be implemented to achieve the same functionality within the scope of this disclosure.

The process parameters and sequence of the steps described and/or illustrated herein are given by way of example only and can be varied as desired. For example, while the steps illustrated and/or described herein are shown or discussed in a particular order, these steps do not necessarily need to be performed in the order illustrated or discussed. The various exemplary methods described and/or illustrated herein can also omit one or more of the steps described or illustrated herein or include additional steps in addition to those disclosed.

The preceding description has been provided to enable others skilled in the art to best utilize various aspects of the exemplary implementations disclosed herein. This exemplary description is not intended to be exhaustive or to be limited to any precise form disclosed. Many modifications and variations are possible without departing from the spirit and scope of the instant disclosure. The implementations disclosed herein should be considered in all respects illustrative and not restrictive. Reference should be made to the appended claims and their equivalents in determining the scope of the instant disclosure.

Unless otherwise noted, the terms “connected to” and “coupled to” (and their derivatives), as used in the specification and claims, are to be construed as permitting both direct and indirect (i.e., via other elements or components) connection. In addition, the terms “a” or “an,” as used in the specification and claims, are to be construed as meaning “at least one of.” Finally, for ease of use, the terms “including” and “having” (and their derivatives), as used in the specification and claims, are interchangeable with and have the same meaning as the word “comprising.”

What is claimed is:

1. An apparatus comprising:
a die stack; and
a plurality of signals arranged across the die stack, wherein the plurality of signals are manipulated to form a unique identifier for each die included in the die stack.

2. The apparatus of claim 1, wherein the plurality of signals comprise a plurality of immutable binary signals that are manipulated at least in part by swizzling to form the unique identifier for each die included in the die stack.

3. The apparatus of claim 1, wherein the unique identifiers comprise:
a first unique identifier for a first die included in the die stack, the first unique identifier being formed by a first pattern of the plurality of signals; and
a second unique identifier for a second die included in the die stack, the second unique identifier being formed by a second pattern of the plurality of signals.

4. The apparatus of claim 1, wherein the plurality of signals are manipulated at least in part by digital logic to form the unique identifier for each die included in the die stack.

5. The apparatus of claim 4, wherein the unique identifiers collectively amount to a number that is at least twice as high as a total number of signals included in the plurality of signals.

6. The apparatus of claim 4, wherein the digital logic comprises at least one of:
a linear-feedback shift register;
a digital adder; or
a digital subtractor.

7. The apparatus of claim 1, wherein the plurality of signals comprises:
a first signal that is shifted in one direction relative to a certain sequence between a first die and a second die included in the die stack; and
second and third signals that are shifted in another direction opposite the one direction between the first die and the second die.

8. The apparatus of claim 7, wherein:
the certain sequence comprises a first position, a second position, and a third position aligned across the die stack; and
the plurality of signals comprises:
a first signal coupled to the first position on the first die;
a second signal coupled to the second position on the first die; and
a third signal coupled to the third position on the first die.

9. The apparatus of claim 8, wherein:
the first signal is shifted to a final position in the certain sequence on the second die;
the second signal is shifted to the first position on the second die; and
the third signal is shifted to the second position on the second die.

10. The apparatus of claim 9, wherein the final position in the certain sequence is the third position.

11. The apparatus of claim 9, wherein the plurality of signals comprises a fourth signal that is coupled to a fourth position in the certain sequence on the first die and is shifted to the third position on the second die.

12. The apparatus of claim 11, wherein:
the first signal is shifted to the third position on a third die included in the die stack;
the second signal is shifted to the final position on the third die;
the third signal is shifted to the first position on the third die; and
the fourth signal is shifted to the second position on the third die.

13. The apparatus of claim 12, wherein:
the first signal is shifted to the second position on a fourth die included in the die stack;
the second signal is shifted to the third position on the fourth die;
the third signal is shifted to the final position on the fourth die; and
the fourth signal is shifted to the first position on the fourth die.

14. The apparatus of claim 13, wherein the first die, the second die, the third die, and the fourth die are duplicates of one another.

15. The apparatus of claim 8, wherein:
the certain sequence is arranged at a specific location relative to the first die; and
the certain sequence is arranged at the specific location relative to the second die.

16. The apparatus of claim 1, further comprising a base die that is coupled to the die stack, wherein a number of dies included in the die stack corresponds to a number of signals included in the plurality of signals.

17. A system comprising:
a base die;
a die stack; and
a plurality of signals arranged across the die stack, wherein the plurality of signals are manipulated to form a unique identifier for each die included in the die stack.

18. The system of claim 17, wherein the plurality of signals comprise a plurality of immutable binary signals that are manipulated at least in part by swizzling to form the unique identifier for each die included in the die stack.

19. The system of claim 17, wherein the plurality of signals are manipulated at least in part by digital logic to form the unique identifier for each die included in the die stack.

20. A method comprising:
coupling a base die to a die stack;
arranging a plurality of signals across the die stack; and
manipulating the plurality of signals to form a unique identifier for each die included in the die stack.
